(19) United States
(12) Patent Application Publication
(10) Pub. No.: US 2023/0400773 A1
(43) Pub. Date: Dec. 14, 2023

(54) EXPOSURE APPARATUS AND WIRING PATTERN FORMING METHOD

(71) Applicant: NIKON CORPORATION, Tokyo (JP)

(72) Inventors: Masaki KATO, Yokohama-shi (JP); Yasushi MIZUNO, Saitama-shi (JP)

(73) Assignee: NIKON CORPORATION, Tokyo (JP)

(21) Appl. No.: 18/238,027

(22) Filed: Aug. 25, 2023

Related U.S. Application Data
(63) Continuation of application No. PCT/JP2022/008212, filed on Feb. 28, 2022.

(30) Foreign Application Priority Data
Apr. 9, 2021 (JP) 2021-066770

(51) Int. Cl. G03F 7/00

(52) U.S. Cl. CPC G03F 7/70291; G03F 7/70508; G03F 7/70825

(57) ABSTRACT

An exposure apparatus includes a spatial light modulator (SLM), a generation unit that acquires a measurement result from a measurement system measuring positions of semiconductor chips arranged on a first substrate, determines a wiring connecting the semiconductor chips based on the measurement result, generates control data used for control of the SLM in generating the determined wiring pattern, and stores the control data in a storage unit, and an exposure processing unit that controls the SLM using the control data stored in the storage unit and exposes the wiring pattern, wherein at least one of measurement of the positions of the semiconductor chips on the first substrate, acquisition of the measurement result, determination of the wiring pattern, generation of the control data, or storage of the control data is executed while the exposure processing unit is performing exposure processing on a second substrate different from the first substrate.

### CROSS-REFERENCE TO RELATED APPLICATION

This application is a continuation application of the prior International Patent Application No. PCT/JP2022/008212, filed on Feb. 28, 2022, based upon and claims the benefit of priority of Japanese Patent Application No. 2021-066770, filed on Apr. 9, 2021, the entire contents of which are incorporated herein by reference.

### FIELD

The present disclosure relates to an exposure apparatus and a wiring pattern forming method.

### BACKGROUND

In recent years, semiconductor device packages called FO-WLP (Fan Out Wafer Level Package) and FO-PLP (Fan Out Plate Level Package) have been known.

For example, in the manufacture of the FO-WLP, a plurality of semiconductor chips are arranged on a wafer-shaped support substrate and fixed using a molding material such as a resin to form a pseudo wafer, and a rewiring layer for connecting pads of the semiconductor chips is formed using an exposure apparatus.

It is desired to improve the throughput in forming the rewiring layer of the FO-WLP and the FO-PLP as disclosed in, for example, Japanese Patent Application Laid-Open No. 2018-081281.

### SUMMARY

According to an aspect of the present disclosure, there is provided an exposure apparatus including: a spatial light modulator; a generation unit configured to acquire a measurement result from a measurement system that measures positions of semiconductor chips included in each of sets of the semiconductor chips arranged on a first substrate, determine a wiring pattern that connects the semiconductor chips included in each of the sets based on the measurement result, generate first control data used for control of the spatial light modulator in generating the determined wiring pattern, and store the first control data in a first storage unit; and an exposure processing unit configured to control the spatial light modulator using the first control data stored in the first storage unit and expose the wiring pattern that connects the semiconductor chips included in each of the sets, wherein at least one of measurement of the positions of the semiconductor chips on the first substrate, acquisition of the measurement result, determination of the wiring pattern, generation of the first control data, or storage of the first control data in the first storage unit is executed while the exposure processing unit is performing exposure processing on a second substrate different from the first substrate.

Note that the configurations of the embodiments described below may be appropriately improved, and at least a part of the components may be replaced with another component. Furthermore, constituent elements whose arrangement is not particularly limited are not limited to the arrangement disclosed in the embodiment, and can be arranged at positions where their functions can be achieved.

### BRIEF DESCRIPTION OF DRAWINGS

FIG. 1 is a top view illustrating an outline of a wiring pattern forming system of an FO-WLP including an exposure apparatus in accordance with a first embodiment;

FIG. 2 is a perspective view schematically illustrating a configuration of the exposure apparatus in accordance with the first embodiment;

FIG. 3A and FIG. 3B are views for describing wiring patterns formed by the wiring pattern forming system;

FIG. 4 is a view for describing modules arranged on an optical surface plate;

FIG. 5A is a view illustrating an optical system of an illumination-projection module, FIG. 5B is a view schematically illustrating a DMD, FIG. 5C is a view illustrating the DMD when the power source is OFF, FIG. 5D is a view for describing a mirror in an ON state, and FIG. 5E is a view for describing a mirror in an OFF state;

FIG. 6 is an enlarged view of the vicinity of the illumination-projection module;

FIG. 7 is a block diagram illustrating a control system of the exposure apparatus in accordance with the first embodiment;

FIG. 8A is a schematic view illustrating a wafer WF in a state where all chips are arranged at design positions, and FIG. 8B is a schematic view illustrating a wafer WF in which chips are arranged in shifted positions from the design positions;

FIG. 9 is a conceptual diagram illustrating a formation procedure of the wiring patterns of the FO-WLP in the exposure apparatus;

FIG. 10 is a top view illustrating an outline of a wiring pattern forming system in accordance with a second embodiment;

FIG. 11 is a conceptual diagram of a manufacturing procedure of the FO-WLP in the second embodiment; and

FIG. 12 is a top view illustrating an outline of a wiring pattern forming system in accordance with a third embodiment.

### DESCRIPTION OF EMBODIMENTS

### First Embodiment

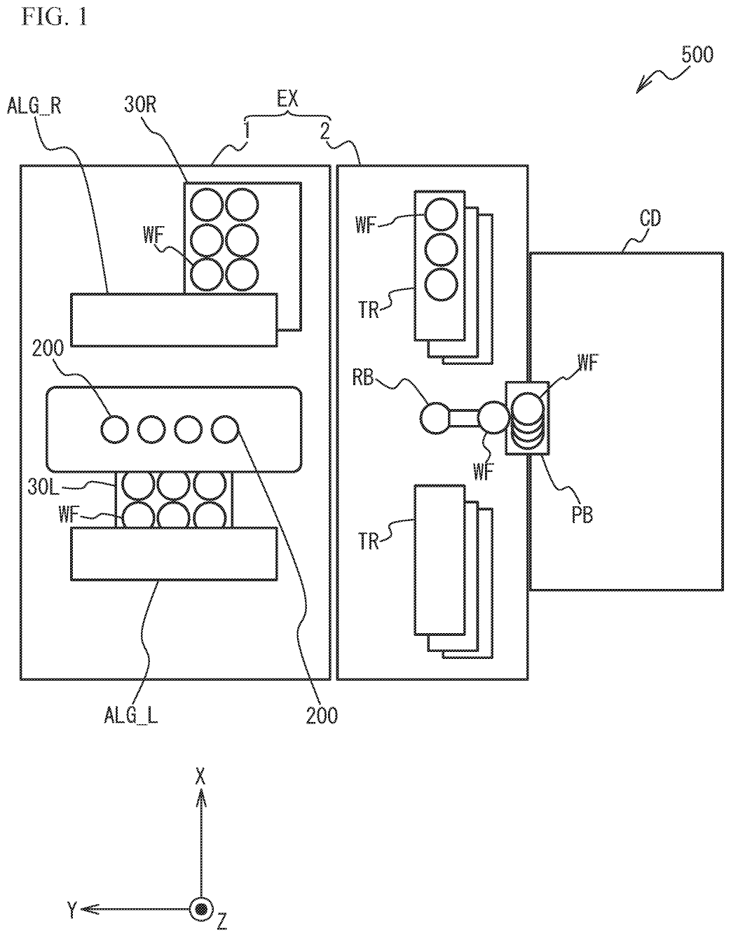

An exposure apparatus in accordance with a first embodiment will be described with reference to FIG. 1 to FIG. 9. In the following description, when simply referred to as a substrate P, it indicates a rectangular substrate, and a wafer-shaped substrate is referred to as a wafer WF. The normal direction of the substrate P or wafer WF placed on a substrate stage 30 described later is referred to as the Z-axis direction, the direction in which the substrate P or wafer WF is relatively scanned with respect to a spatial light modulator (SLM) in a plane perpendicular to the Z-axis direction is referred to as the X-axis direction, the direction perpendicular to the Z-axis and the Y-axis is referred to as the Y-axis direction, and the directions of rotation (tilt) about the X-axis, Y-axis, and Z-axis are referred to as θx, θy, and θz directions, respectively. Examples of the spatial light modulator include a liquid crystal element, a digital mirror device (digital micromirror device, DMD), and a magneto-optic spatial light modulator (MOSLM). The exposure apparatus EX in accordance with the first embodiment includes a DMD 204 as the spatial light modulator, but may include other spatial light modulators.

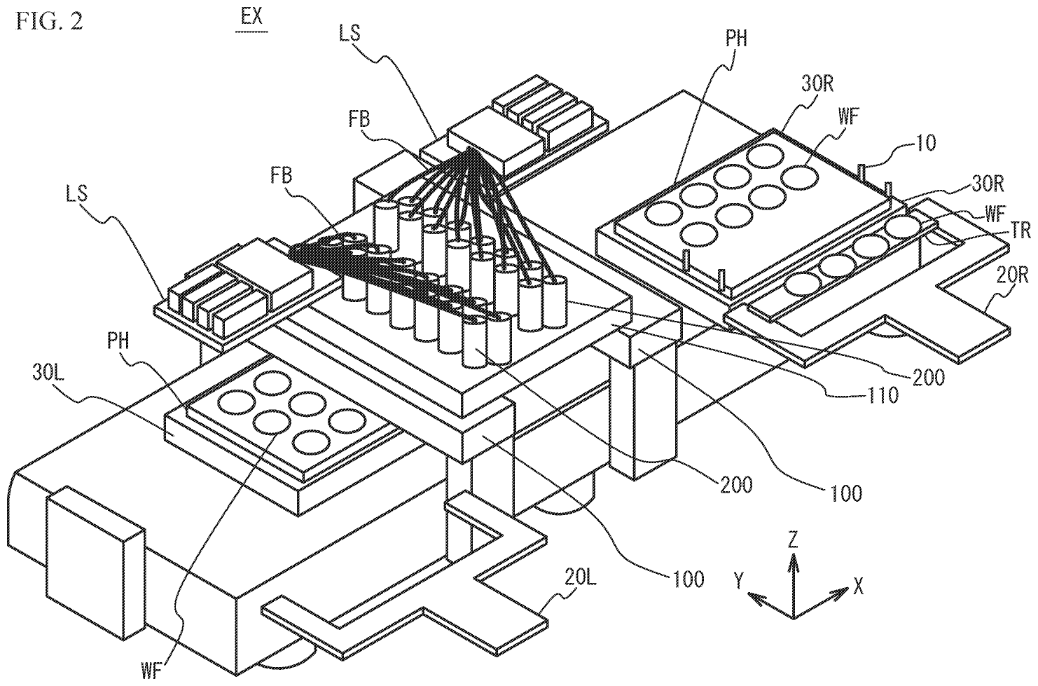

FIG. 1 is a top view illustrating an outline of a wiring pattern forming system 500 for the FO-WLP and FO-PLP including an exposure apparatus EX in accordance with one embodiment. FIG. 2 is a perspective view schematically illustrating a configuration of the exposure apparatus EX.

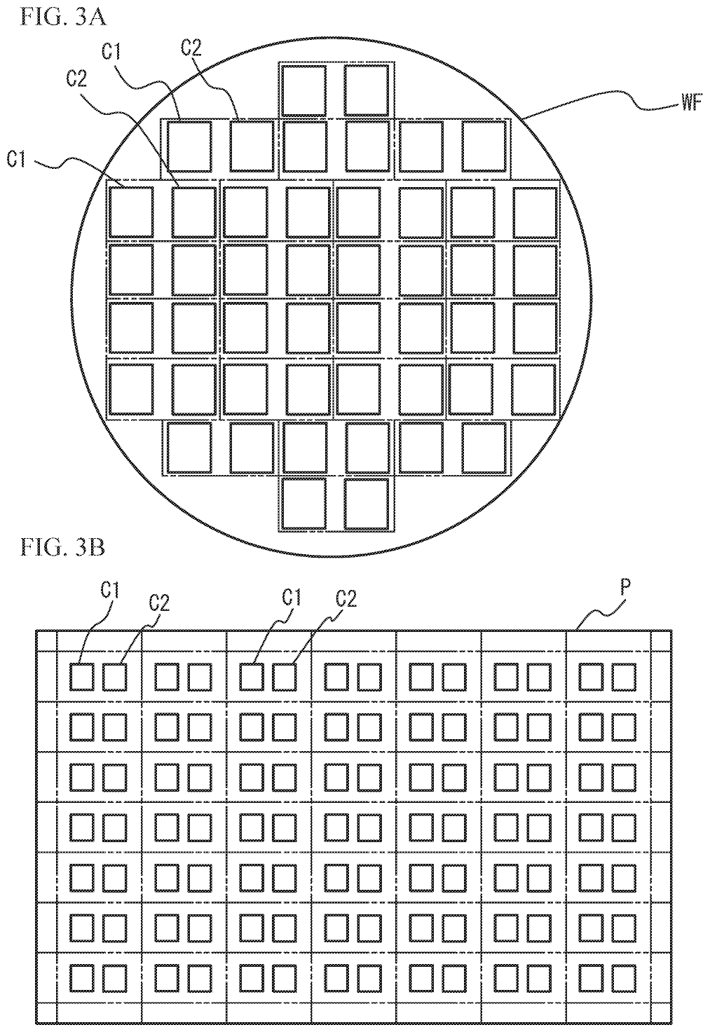

The wiring pattern forming system 500 is a system for forming wiring patterns that connect semiconductor chips (hereinafter referred to as chips) arranged on a wafer WF as illustrated in FIG. 3A or chips arranged on a substrate P as illustrated in FIG. 3B.

In the present embodiment, a wiring pattern is formed to connect chips C1 and C2 included in each of a plurality of sets of chips (indicated by two dot chain lines) arranged on the wafer WF or the substrate P. In the present embodiment, the number of chips included in each set is two, but is not limited to this, and may be three or more.

Hereinafter, a case where wiring patterns for connecting chips arranged on the wafer WF is formed will be described.

As illustrated in FIG. 1, the wiring pattern forming system 500 includes a coater/developer apparatus CD and the exposure apparatus EX.

The coater/developer apparatus CD applies a photosensitive resist to the wafer WF. The wafer WF coated with the resist is carried into a buffer section PB capable of stocking a plurality of wafers WF. The buffer section PB also serves as a delivery port for the wafer WF.

More specifically, the buffer section PB is composed of a carry-in section and a carry-out section. Wafers WF coated with a resist are carried into the carry-in section one by one from the coater/developer apparatus CD. The wafers WF coated with the resist are carried from the coater/developer apparatus CD into the carry-in section one by one at predetermined time intervals, and a plurality of the wafers WF are collectively loaded on a tray TR described later, so that the carry-in section functions as a buffer for storing the wafers WF.

Further, the carry-out section functions as a buffer when the exposed wafer WF is carried out to the coater/developer apparatus CD. The coater/developer apparatus CD can take out the exposed wafers WF only one at a time. Therefore, the tray TR on which a plurality of the exposed wafers WF are loaded is placed in the carry-out section. This allows the coater/developer apparatus CD to remove the exposed wafers WF one by one from the tray TR.

The exposure apparatus EX includes a main unit 1 and a substrate exchange unit 2. As illustrated in FIG. 1, a robot RB is installed in the substrate exchange unit 2. The robot RB arranges a plurality of wafers WF placed in the buffer section PB on one tray TR.

As illustrated in FIG. 1 and FIG. 2, in the first embodiment, it is possible to place 4 wafers WF×3 rows on each of substrate stages 30R and 30L described later. The tray TR in accordance with the first embodiment is a lattice-shaped tray in which 4 wafers WF×1 row can be sequentially placed on each of the substrate stages 30R and 30L. The tray TR may be a tray that can place the wafers WF on the entire surface of each of the substrate stages 30R and 30L at a time (i.e., a tray on which 4 wafers WF×3 rows can be arranged).

As illustrated in FIG. 2, the substrate exchange unit 2 includes exchange arms 20R and 20L. The exchange arm 20R carries in and out the wafers WF (more specifically, the tray TR on which a plurality of the wafers WF are placed) to and from a substrate holder PH of the substrate stage 30R, and the exchange arm 20L carries in and out the wafers WF to and from the substrate holder PH of the substrate stage 30L. In the following description, the exchange arms 20R and 20L will be referred to as an exchange arm 20 unless they need to be distinguished from each other. In addition, the substrate holder PH is not illustrated except in FIG. 2.

Generally, each of the exchange arms 20R and 20L includes a carry-in arm for carrying in the tray TR and a carry-out arm for carrying out the tray TR. This configuration allows the tray TR to be replaced at high speed. When the wafer WF is carried in, the lattice-shaped tray TR is supported by substrate exchange pins 10. When the substrate exchange pins 10 are lowered, the tray TR sinks into grooves (not illustrated) formed in the substrate stage 30, and the wafer WF is sucked and held by the substrate holder PH on the substrate stage 30. When one row of substrates is placed on the tray TR as illustrated in FIG. 2, the positions of the substrate stages 30R and 30L or the positions of the exchange arms 20R and 20L are changed in accordance with the position where the tray TR is to be placed on the substrate stages 30R and 30L, respectively.

When the wafer WF is sucked to the substrate holder PH, the position of the alignment mark or the pad of the wiring line of the wafer WF is measured by an alignment system ALG-R or ALG-L mounted on an optical surface plate 110. Normally, in the measurement of the position of each wafer WF, the number of measurement points and the arrangement of the measurement points are determined so that six parameters: X-direction shift (X), Y-direction shift (Y), rotation (Rot), X-direction magnification (X_Mag), Y-direction magnification (Y_Mag), and orthogonality (Oth) of the wafer WF placed on the substrate holder PH can be calculated.

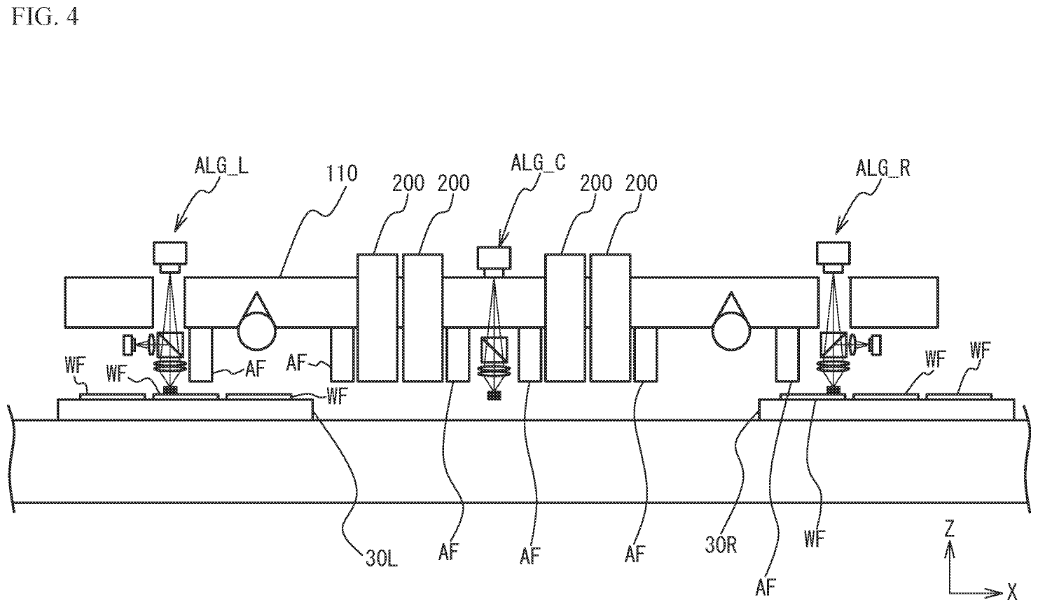

On the optical surface plate 110 kinematically supported on a column 100, a plurality of illumination-projection modules 200, autofocus systems AF, and alignment systems ALG_R, ALG_L, and ALG_C are arranged, as illustrated in FIG. 4.

As illustrated in FIG. 2, in the present embodiment, a plurality of columns (four columns in FIG. 2) each including a plurality of the illumination-projection modules 200 are arranged. In FIG. 1, only one column including a plurality of the illumination-projection modules 200 is illustrated for simplicity. Further, in FIG. 2, the alignment systems ALG_R and ALG_L are not illustrated for simplification.

A plurality of the illumination-projection modules 200 are only required to be provided so that the wiring patterns in different sets can be exposed at a time. The number of columns of the illumination-projection modules 200 may be one to three or five or more. The number of the illumination-projection modules 200 included in each column is only required to be two or more. In addition, when a plurality of wafers WF are placed on the substrate holder, different sets exposed at a time by the illumination-projection modules 200 may be different sets in the same wafer WF or may be sets in different wafers WF.

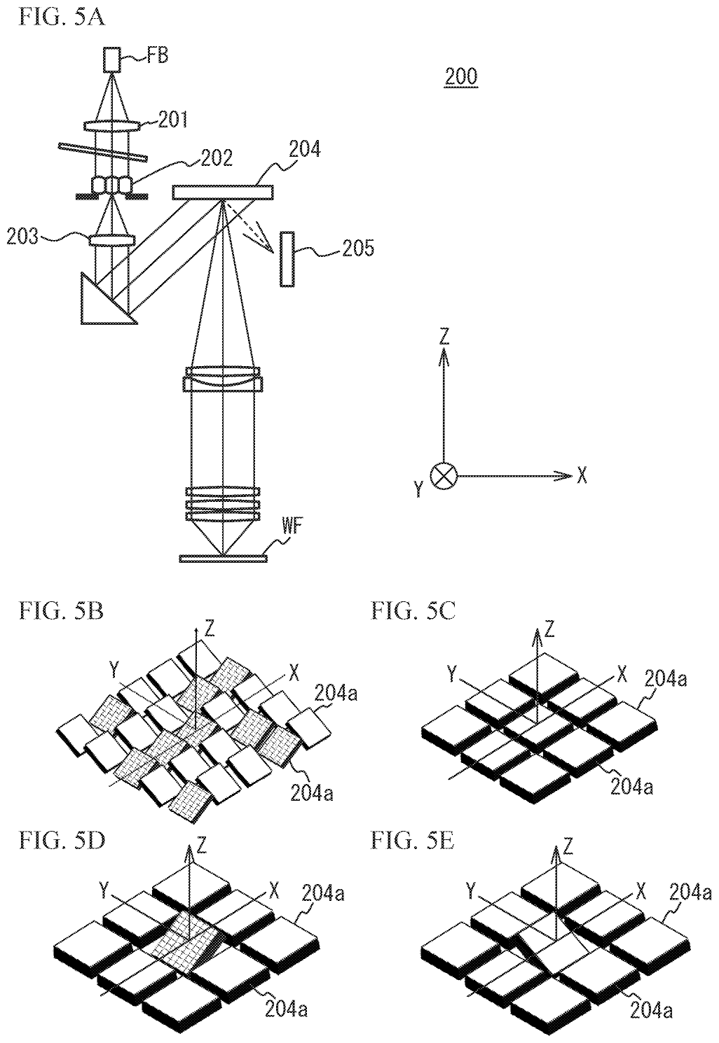

FIG. 5A illustrates an optical system of the illumination-projection module 200. The illumination-projection module 200 includes a collimator lens 201, a fly-eye lens 202, a main condenser lens 203, and the DMD 204.

The laser light emitted from a light source LS is taken into the illumination-projection module 200 through a delivery fiber FB. The laser light passes through the collimator lens 201, the fly-eye lens 202, and the main condenser lens 203 to substantially uniformly illuminate the DMD 204.

FIG. 5B is a view schematically illustrating the DMD 204, and FIG. 5C illustrates the DMD 204 when the power supply is off. In FIG. 5B to FIG. 5E, the mirrors in an ON state are indicated by hatching.

The DMD 204 has a plurality of micro mirrors 204a that can be controlled to change the reflection angle. Each micro mirror 204a becomes in an ON state by tilting around the Y-axis. FIG. 5D illustrates a case where only the central micro mirror 204a is in the ON state and the other micro mirrors 204a are in a neutral state (a state neither ON nor OFF). Each micro mirror 204a becomes in an OFF state by tilting around the X-axis. FIG. 5E illustrates a case where only the central micro mirror 204a is in the OFF state and other micro mirrors 204a are in the neutral state. The DMD 204 switches between the ON state and the OFF state of each micro mirror 204a to generate an exposure pattern (hereinafter, referred to as a wiring pattern) of wiring lines connecting the chips.

As illustrated in FIG. 5A, the illumination light reflected by the mirror in the OFF state is absorbed by an OFF-light absorbing plate 205. The illumination-projection module 200 has a magnification for projecting one pixel of the DMD 204 in a predetermined size, and can slightly correct the magnification by focusing by Z-axis driving of the lens and driving some of the lens. In addition, the DMD 204 itself can be driven in the X direction, the Y direction, and the Oz direction, and corrects, for example, a deviation from a target value of the substrate stage 30.

Since the DMD 204 is described as an example of the spatial light modulator, the spatial light modulator is described as a reflective spatial light modulator that reflects laser light, but the spatial light modulator may be a transmissive spatial light modulator that transmits laser light or a diffractive spatial light modulator that diffracts laser light. The spatial light modulator can spatially and temporally modulate the laser light.

Referring back to FIG. 4, the autofocus systems AF are disposed so as to sandwich the illumination-projection modules 200. Thus, regardless of the scanning direction of the wafer WF, the measurement can be performed by the autofocus systems AF before the exposure operation for forming the wiring patterns that connect the chips arranged on the wafer WF.

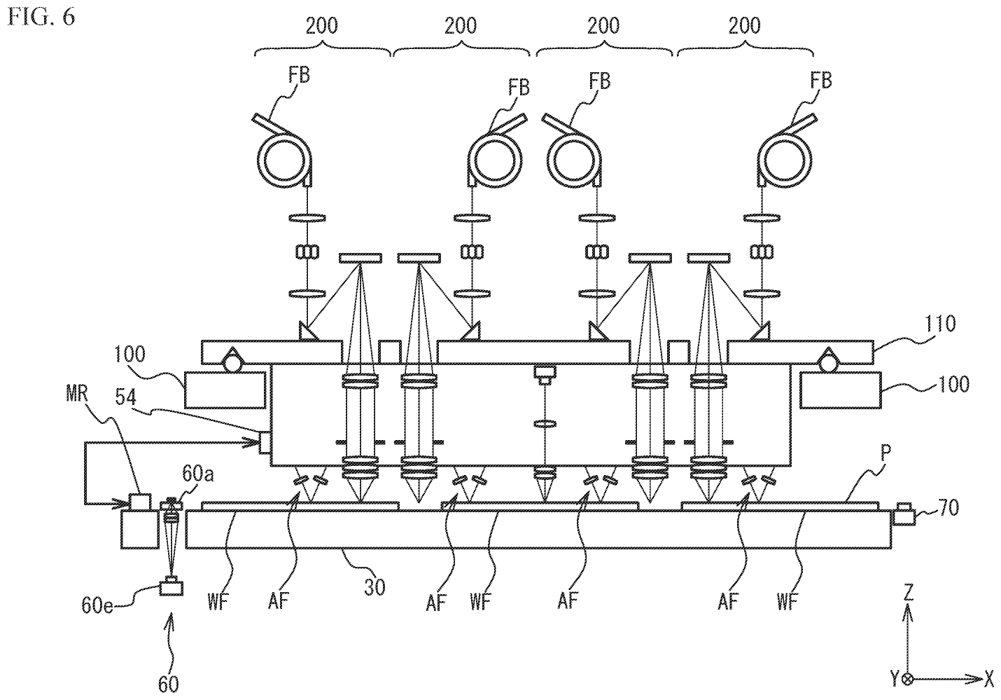

FIG. 6 is an enlarged view of the vicinity of the illumination-projection module 200. As illustrated in FIG. 6, a fixed mirror 54 for measuring the position of the substrate stage 30 is provided near the illumination-projection module 200.

As illustrated in FIG. 6, the substrate stage 30 is provided with an alignment device 60. The alignment device 60 includes a reference mark 60a, a two-dimensional image sensor 60e, and the like. The alignment device 60 is used for measuring and calibrating the positions of various modules, and is also used for calibrating the alignment systems ALG_R, ALG_L, and ALG_C arranged on the optical surface plate 110.

In the measurement and calibration of the position of each module, the position of each module is measured by projecting a DMD pattern for calibration onto the reference mark 60a of the alignment device 60 by the illumination-projection module 200 and measuring the relative position between the reference mark 60a and the DMD pattern.

Further, the alignment systems ALG_R, ALG_L, and ALG_C can be calibrated by measuring the reference mark 60a of the alignment device 60 by the alignment systems ALG_R, ALG_L, and ALG_C. That is, the positions of the alignment systems ALG_R, ALG_L, and ALG_C can be obtained by measuring the reference mark 60a of the alignment device 60 by the alignment systems ALG_R, ALG_L, and ALG_C. Furthermore, the relative position to the position of the module can be determined by using the reference mark 60a.

The substrate stage 30 is provided with a moving mirror MR, a DM monitor 70, and the like, which are used to measure the position of the substrate stage 30.

Each of the alignment systems ALG_R and ALG_L includes a plurality of measurement microscopes, and measures the positions of chips arranged on each wafer WF placed on the substrate holder of the substrate stage 30 or the positions of the pads of the chips to be wired with reference to the reference mark 60a of the alignment device 60. More specifically, the alignment systems ALG_R and ALG_L measure the position of each chip based on the design position of each chip with respect to the reference mark 60a. The measurement results are output to a data generation device 300 described later.

The alignment system ALG_C measures the position of the wafer WF placed on the substrate holder of the substrate stage 30 with respect to the reference mark 60a of the alignment device 60, before starting exposure. Based on the measurement results of the alignment system ALG_C, the positional shift of the wafer WF with respect to the substrate stage 30 is detected, and the exposure start position and the like are changed.

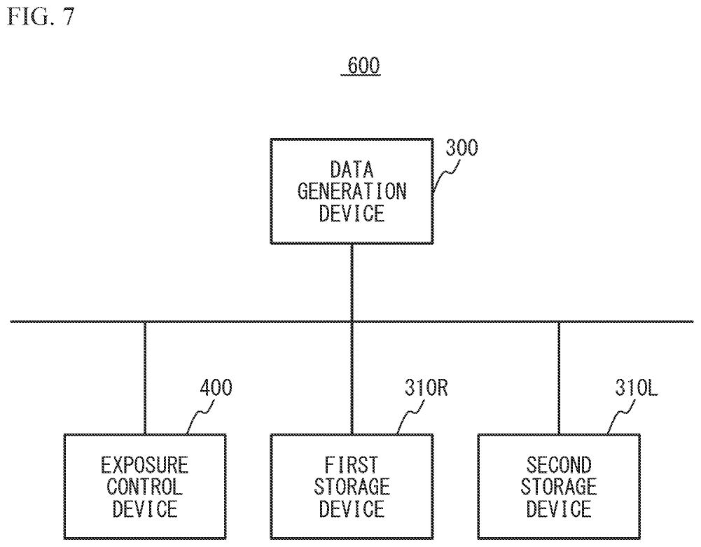

FIG. 7 is a block diagram illustrating a control system 600 of the exposure apparatus EX in accordance with the present embodiment. As illustrated in FIG. 7, the control system 600 includes the data generation device 300, a first storage device 310R, a second storage device 310L, and an exposure control device 400.

The data generation device 300 receives, from the alignment systems ALG_R and ALG_L, measurement results of the position of each chip or the position of the pad of each chip provided on the wafer WF placed on the substrate holder of the substrate stage 30. The data generation device 300 determines a wiring pattern for connecting the chips based on the measurement result of the position of each chip, and generates a control data used to control the DMD 204 in generating the determined wiring pattern. Next, generation of the control data will be described in more detail.

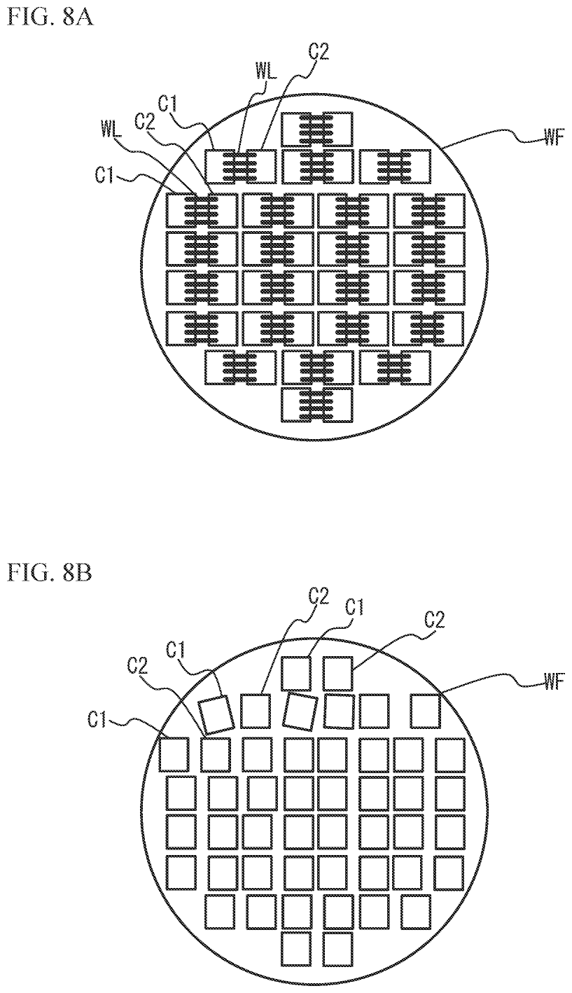

FIG. 8A is a schematic view illustrating the wafer WF in a state where all chips are arranged at positions as designed (hereinafter referred to as design positions). As illustrated in FIG. 8A, a wiring pattern WL connecting the chips C1 and C2 is exposed (formed) by the exposure apparatus EX. Here, in the FO-WLP, since the chips are fixed on the wafer WF by a mold material such as a resin, the position of each chip may be shifted from the design position as illustrated in FIG. 8B. In this case, when the DMD 204 is controlled and the wiring pattern is exposed by using data indicating the wiring pattern for connecting the chips at the design positions (hereinafter referred to as design-value data), the wiring pattern may be displaced from the position of the pad, resulting in a poor connection or short circuit.

Therefore, in the present embodiment, the alignment system ALG_R or ALG_L measures the positions of chips included in each of a plurality of sets of chips arranged on the wafer WF. The data generation device 300 generates wiring pattern data obtained by correcting part of the design value data based on the measurement results acquired from the alignment system ALG_R or ALG_L.

The generated wiring pattern data is stored in the first storage device 310R or the second storage device 310L. The first storage device 310R and the second storage device 310L are, for example, solid state drives (SSDs).

The first storage device 310R stores wring pattern data used to control the DMD 204 in exposing the wafer WF placed on the substrate stage 30R. The second storage device 310L stores wiring pattern data used to control the DMD 204 in exposing the wafer WF placed on the substrate stage 30L. The wiring pattern data stored in the first storage device 310R or the second storage device 310L is transferred to the exposure control device 400.

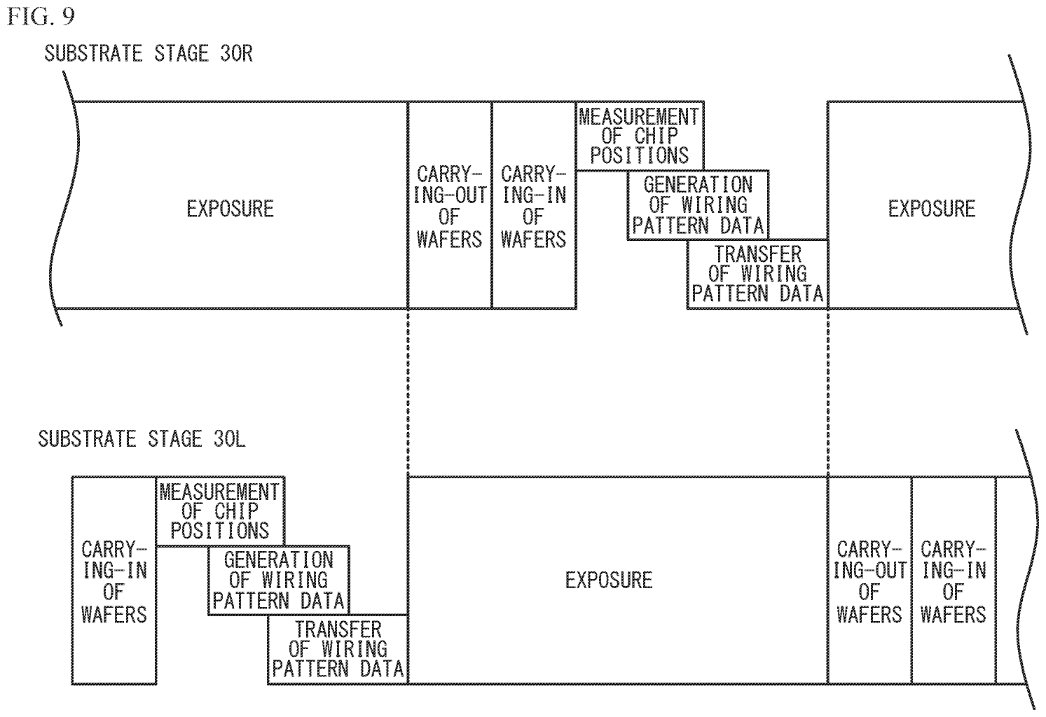

Next, an example of a procedure for forming wiring patterns of the FO-WLP in the exposure apparatus EX of the present embodiment will be described. FIG. 9 is a conceptual diagram of a procedure for forming wiring patterns of the FO-WLP in the exposure apparatus EX.

As illustrated in FIG. 9, in the present embodiment, for example, while the wafer WF on the substrate stage 30R is being subjected to exposure processing, the wafers WF are carried onto the substrate stage 30L and the chip positions are measured by the alignment system ALG_L. Based on the measurement results of the chip positions, the data generation device 300 sequentially generates the wiring pattern data and stores (transfers) the generated wiring pattern data in the second storage device 310L. The wiring pattern data stored in the second storage device 310L is sequentially transferred to the exposure control device 400 in synchronism with the start of exposure of the wafers WF on the substrate stage 30L.

In the case that 4 wafers WF×1 row are arranged on one tray TR as illustrated in FIG. 2, the tray TR may be placed on the substrate stage 30L when loading of four wafers onto one tray TR is finished, and the alignment system ALG_L may start measuring the chip positions. In this case, the measurement of the chip positions by the alignment system ALG_L and the process of loading other wafers WF on the next tray TR can be performed in parallel. Then, in parallel with the process of placing the tray TR on which other wafers WF are arranged onto the substrate stage 30L, the process of generating the wiring pattern data for the wafer WF whose chip positions have already been measured based on the measurement results by the alignment system ALG_L and storing it in the second storage device 310L can be performed. Such parallel processing is particularly effective when it takes time to generate, transfer and store the wiring pattern data. When the time required for the measurement of the chip positions and the generation and storage of the wiring pattern data is shorter than the exposure time, for example, 4 wafers WF×3 rows may be placed on one tray TR and then carried onto the substrate stage 30L to perform the measurement by the alignment system ALG_L. In the placement processing, any one of a placement operation of placing the wafers WF on the tray TR and a placement preparation operation of preparing for placing the wafers WF on the tray TR may be performed.

On the other hand, when the exposure of the wafers WF on the substrate stage 30L is started, the exposed wafers WF on the substrate stage 30R are unloaded and then new wafers WF are loaded onto the substrate stage 30R. Thereafter, measurement of the chip positions by the alignment system ALG_R is performed. Based on the measurement results of the chip positions, the data generation device 300 sequentially generates the wiring pattern data and transfers the generated wiring pattern data to the first storage device 310R. The wiring pattern data stored in the first storage device 310R is sequentially transferred to the exposure control device 400 as exposure of the wafers WF on the substrate stage 30R starts.

As described above, in the present embodiment, while one of the two substrate stages 30R and 30L is used to perform exposure processing, the exposed wafers are carried out, new wafers are carried in, the chip positions are measured, and the wiring pattern data is generated and transferred in the other substrate stage. By performing parallel processing using the two substrate stages 30R and 30L in this manner, the time required for the measurement of the chip positions and the process of generating and transferring the wiring pattern data can be hidden in the time required for the exposure processing. As a result, the throughput in forming the wiring patterns of the FO-WLP can be improved. The exposure processing includes a series of operations from driving of the substrate stage for performing exposure to driving of the substrate stage to the substrate exchange position after completion of the exposure.

As described above in detail, the exposure apparatus EX according to the first embodiment includes the spatial light modulators (DMD 204 in the first embodiment), the data generation device 300, and the exposure control device 400. The exposure apparatus EX also includes a plurality of the substrate stages 30R and 30L and the alignment systems ALG_R and ALG_L. The alignment system ALG_L measures the positions of the chips C1 and C2 included in each of a plurality of sets of semiconductor chips arranged on the wafer WF placed on the substrate stage 30L while the wiring patterns are exposed on the wafer WF placed on the substrate stage 30L. The data generation device 300 acquires measurement results from the alignment system ALG L, and determines, based on the measurement results, the wiring pattern WL that connects between the chip C1 and the chip C2 included in each of the sets of chips arranged on the wafer WF on the substrate stage 30L. Then, the data generation device 300 generates wiring pattern data used to control the DMD 204 in generating the determined wiring pattern WL, and stores the generated wiring pattern data in the second storage device 310L. When the exposure processing in the substrate stage 30R is completed, the exposure control device 400 controls the DMD 204 using the wiring pattern data stored in the second storage device 310L to expose the wiring pattern WL connecting the chips C1 and C2 included in each set on the wafer WF placed on the substrate stage 30L. As a result, while the wafers WF on the substrate stage 30R are being subjected to exposure processing, the positions of the chips on the substrate placed on the substrate stage 30L can be measured, and the wiring pattern data based on the measurement results can be generated and transferred. As a result, the time can be effectively used, and thereby, the throughput in forming the wiring patterns of the FO-WLP can be improved.

In the first embodiment, a plurality of the wafers WF are arranged on each of the substrate stages 30R and 30L of the exposure apparatus EX. As a result, the wiring patterns for connecting the semiconductor chips can be formed on the wafers WF, thereby, improving the throughput in the formation of the wiring patterns of the FO-WLP.

In the first embodiment, the exposure apparatus EX includes a plurality of the exchange arms 20R and 20L for exchanging the wafers WF held by the substrate stages 30R and 30L, respectively. For example, while the wafers WF on the substrate stage 30R are being subjected to the exposure processing, the exchange arm 20L exchanges the wafers WF on the substrate stage 30L. As a result, the time can be effectively used, thereby improving the throughput in forming the wiring patterns of the FO-WLP.

Further, in the first embodiment, the exposure apparatus EX includes a plurality of the DMDs 204, and each of the DMDs 204 forms wiring patterns that connect chips in different sets. This allows the simultaneous formation of the wiring patterns that connect semiconductor chips in different sets, thus improving throughput in the formation of the wiring patterns of the FO-WLP.

In the first embodiment described above, while one of the two substrate stages 30R and 30L is used to perform exposure processing, unloading of exposed wafers, loading of new wafers, measurement of chip positions, and generation and transfer of wiring pattern data are performed in the other substrate stage, but this does not intend to suggest any limitation. While exposure processing is being performed using one of the two substrate stages 30R and 30L, at least one of unloading of exposed wafers, loading of new wafers, measurement of chip positions, or generation and transfer of wiring patterns may be performed in the other substrate stage.

(Variation)

The data generation device 300 may generate drive data defining the drive amount of the DMD 204 and the drive amount of the lens actuator instead of the wiring pattern data. That is, the DMD 204 may generate the wiring pattern data using the design value data, and change the drive amount of the DMD 204 and the drive amount of the lens actuator to change the positions of the projection images of the wiring patterns projected onto the wafer WF, thereby changing the shapes of the wiring patterns formed on the wafer WF. The shapes of the wiring patterns may be changed by optically correcting the images of the wiring patterns.

### Second Embodiment

Since the step of attaching the chips to the wafer WF is performed before the formation of the wiring patterns in the exposure apparatus EX, the data generation device 300 may generate the wiring pattern data or the drive data using the measurement data acquired in the inspection step of inspecting the position of each chip with respect to the wafer WF.

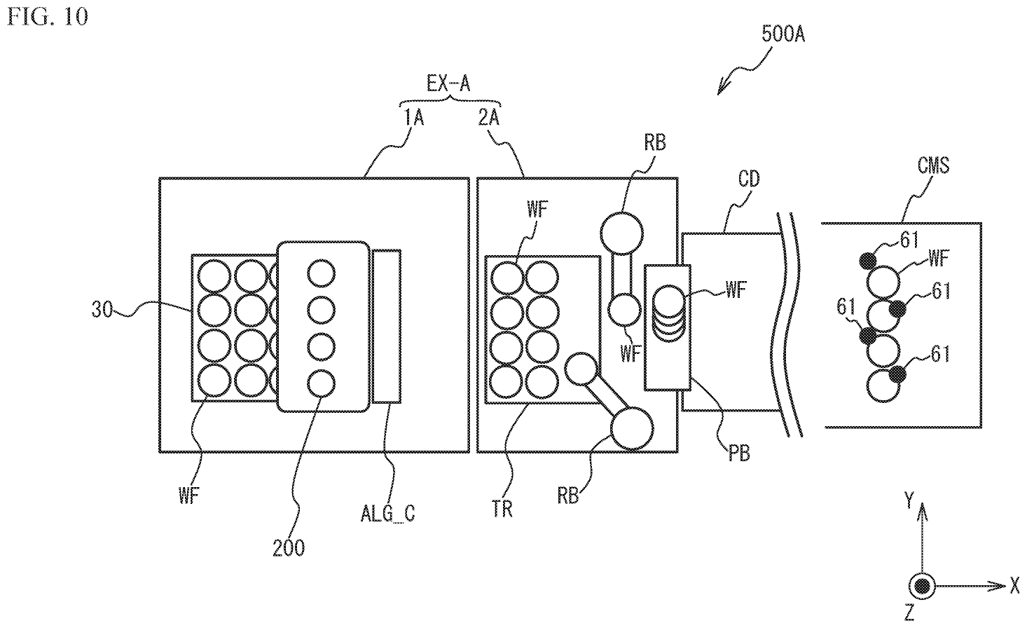

FIG. 10 is a top view illustrating an outline of a wiring pattern forming system 500A in accordance with a second embodiment. The wiring pattern forming system 500A in accordance with the second embodiment includes a chip measurement station CMS for measuring the positions of chips on the wafer WF.

The chip measurement station CMS includes a plurality of measurement microscopes 61 for measuring the positions of chips in different sets. Here, the positions of the chips in the different sets measured by the measurement microscopes 61 may be the positions of the chips in the different sets on the same wafer WF, or the positions of the chips in the respective sets on the different wafers WF. In the present embodiment, the measurement microscopes 61 measure the positions of chips in each set on different wafers WF.

The measurement results of the positions of the chips are transmitted to the data generation device 300. The data generation device 300 generates wiring pattern data (or drive data) based on the measurement results of the chip positions received from the chip measurement station CMS. The wiring pattern data generated by the data generation device 300 is stored in a storage device different from the storage device in which the wiring pattern data used for the exposure control of the substrate currently being exposed is stored. That is, when the wiring pattern data used for the exposure control of the wafer WF currently being exposed is stored in the first storage device 310R, the data generation device 300 stores (transfers) the generated wiring pattern data in the second storage device 310L.

In an exposure apparatus EX-A in accordance with the second embodiment, a main unit 1A includes one substrate stage 30. In the second embodiment, since the chip positions are measured by the chip measurement station CMS, the alignment systems ALG_L and ALG_R can be omitted.

After the measurement of the chip positions is completed, the wafers WF are coated with a photosensitive resist by the coater/developer apparatus CD and then carried into the buffer section PB. The wafers WF placed in the buffer section PB are arranged in plural (4 wafers×3 rows in the second embodiment) on one tray TR by the robot RB installed in a substrate exchange unit 2A, carried into the main unit 1A, and placed on the substrate holder of the substrate stage 30.

The alignment system ALG_C measures the position of each wafer WF with respect to the substrate holder and corrects the exposure start position and the like. When the positions of chips shift from the positions of wiring pattern data generated by the data generation device 300 due to rotation of the wafer WF around the Z axis at the time of placing the wafer WF on the substrate holder, there is a possibility that chips are not connected correctly when wiring lines are formed using the wiring pattern data.

In this case, the data generation device 300 may correct the shape of the wiring pattern so that the chips are connected to each other by generating the wiring pattern data or the drive data as described in the first embodiment and the variation thereof. For example, the data generation device 300 detects the positional shift of each chip from the position of the wiring pattern data, from the position of each wafer WF measured by the alignment system ALG_C based on the positions of the chips with respect to the position of each wafer WF measured by the chip measurement station CMS. The data generation device 300 corrects the wiring pattern data or generates drive data based on the detected shift. As a result, even when the wafer WF is placed on the substrate holder with the wafer WF rotated around the Z axis, it is possible to form the wiring line that connects chips.

The alignment system ALG_C may use an alignment mark of a chip to measure the position of the wafer WF.

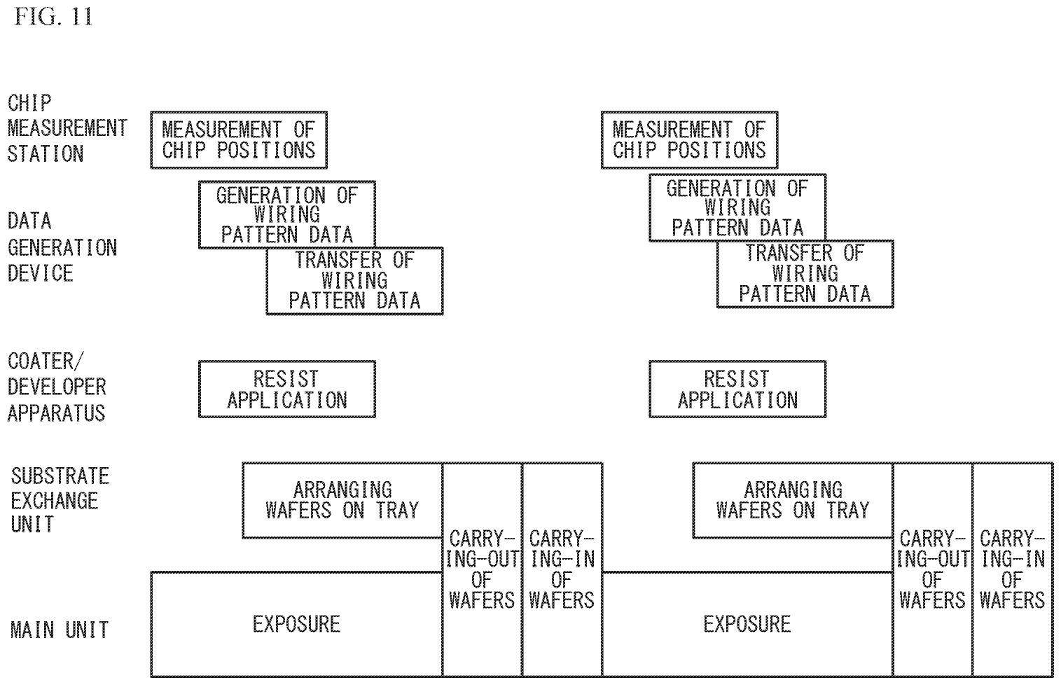

FIG. 11 is a conceptual diagram of a forming procedure of the wiring patterns of the FO-WLP in the second embodiment. As in the first embodiment, during the exposure processing in the main unit 1A, the measurement of the chip positions, the generation and transfer of the wiring pattern data (or the drive data), the application of the resist to the wafers WF, and the placement of the wafers WF on the tray TR are performed. Therefore, the throughput in the formation of the wiring patterns of the FO-WLP can be improved.

The exposure apparatus EX in accordance with the second embodiment includes a spatial light modulator (DMD 204), the data generation device 300, and the exposure control device 400. The data generation device 300 acquires measurement results from the chip measurement station CMS that measures the positions of the chips C1 and C2 included in each of sets of chips arranged on the wafer WF, determines the wiring pattern WL that connects the chips C1 and C2 included in each set based on the measurement results, generates the wiring pattern data used for the control of the DMD 204 in generating the determined wiring pattern WL, and stores it in the first storage device 310R or the second storage device 310L. The exposure control device 400 controls the DMD 204 using the wiring pattern data stored in the first storage device 310R or the second storage device 310L to expose the wiring pattern WL that connects the chips C1 and C2 included in each set. The measurement of the positions of the chips on the wafer WF is performed while a set of the wafers WF different from the set of the wafers WF whose chip positions are measured together with the wafer WF is exposed. This allows the measurement of chip positions and the generation and transfer of wiring pattern data based on the measurement results to be performed during the exposure processing, which takes relatively long time, making effective use of time and thus improving the throughput in the formation of the wiring patterns of the FO-WLP.

### Third Embodiment

The wafers WF may be attached to a base substrate B, and the position of each chip with respect to the base substrate B may be measured in the chip measurement station CMS.

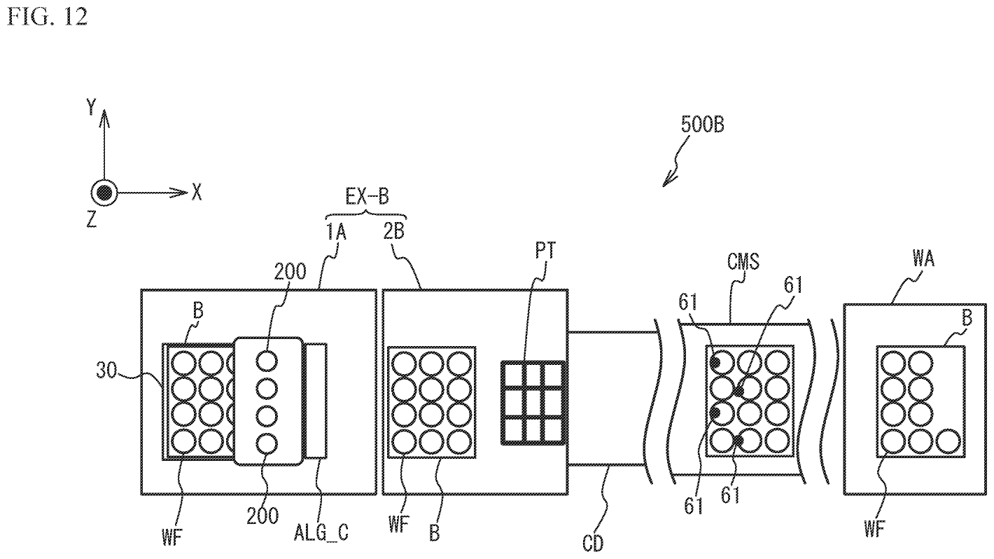

FIG. 12 is a top view illustrating an outline of a wiring pattern forming system 500B in accordance with a third embodiment. The wiring pattern forming system 500B in accordance with the third embodiment has a wafer arrangement device WA for attaching a plurality of wafers WF on which chips are arranged to the base substrate B. The wafer arrangement device WA prevents the position of the wafer WF with respect to the base substrate B from being changed.

The base substrate B to which the wafers WF are attached by the wafer arrangement device WA is carried into the chip measurement station CMS.

The chip measurement station CMS includes a plurality of the measurement microscopes 61 and measures the position of each chip with respect to the base substrate B. The measurement microscopes 61 measure the positions of chips in different sets. The measurement results of the positions of the chips are transmitted to the data generation device 300.

The data generation device 300 generates wiring pattern data (or drive data) based on the measurement results of the chip positions received from the chip measurement station CMS. The wiring pattern data generated by the data generation device 300 is stored in a storage device different from the storage device in which the wiring pattern data used for the control of the exposure of the wafers WF on the base substrate B currently being exposed is stored. That is, when the wiring pattern data used for the control of the exposure of the wafers WF on the base substrate B currently being exposed is stored in the first storage device 310R, the data generation device 300 stores (transfers) the generated wiring pattern data in the second storage device 310L.

After the measurement of the chip positions is completed, the wafers WF are carried into the coater/developer apparatus together with the base substrate B, coated with a photosensitive resist, and then carried into a port PT of a substrate exchange unit 2B. Thereafter, the wafers WF are placed on the substrate holder of the substrate stage 30 together with the base substrate B.

Since the subsequent processing is the same as that in the second embodiment, detailed description thereof will be omitted. In the third embodiment, the position of the base substrate B on which the wafers WF are placed and fixed is used to manage everything and expose the wafers WF. For example, EGA measurement and correction may be performed with respect to the base substrate B also during alignment. In other words, since the wafers WF are placed and fixed on the base substrate B, when the base substrate B is placed on the substrate holder of the substrate stage 30, alignment for each wafer WF/each chip is not required, and alignment of the base substrate B is only required. Although the wafer arrangement device WA attaches the wafers WF to the base substrate B, the wafers WF may be directly placed and fixed on the tray TR.

Also in the third embodiment, it is possible to improve the throughput in the formation of the rewiring layer of the FO-WLP by performing the measurement of the chip positions, the generation and transfer of the wiring pattern data, and the resist application to the wafers WF during the exposure processing in the main unit 1A.

(Variation)

In the third embodiment, the wafer arrangement device WA and the chip measurement station CMS are separate devices, but this does not intend to suggest any limitation. The measurement microscope 61 may start measurement of the chip position from the wafer WF attached to the base substrate B in the wafer arrangement device WA. In other words, the measurement operation is performed by the measurement microscope 61 in parallel with the operation of attaching a plurality of the wafers WF to the base substrate B. The measurement microscope 61 may start the measurement operation after one wafer WF is attached to the base substrate B, or may start the measurement operation after a plurality of the wafers WF are attached to the base substrate B. The measurement microscope 61 may temporarily suspend the measurement operation at the timing when the wafer WF is placed on the base substrate B. This is to prevent the vibration generated when the wafer WF is placed on the base substrate B from affecting the measurement result of the measurement microscope 61.

In the first to third embodiments and their variations, the first storage device 310R and the second storage device 310L are separate storage devices. However, data used for the exposure processing on the wafers WF placed on the substrate stage 30R (at least one of the wiring pattern data or the drive data) and data used for the exposure processing on the wafers WF placed on the substrate stage 30L (at least one of the wiring pattern data or the drive data) may be stored in different storage areas of one storage device. However, in the case that different storage areas of one storage device are used, while one storage area is being accessed, the other storage area cannot be accessed, and thus there is a concern that the processing time as a whole becomes longer. In addition, the deterioration of the SSD progresses each time writing is performed, and the usage time also affects the lifetime thereof. Therefore, since the number of times of writing data to the storage device in the first embodiment is relatively large, when one SSD is used, there is a possibility that the SSD is required to be replaced in a short period. Therefore, it is preferable to use two storage devices.

Although the case where a plurality of wafer-shaped substrates are placed on the substrate stage 30 has been described in the first to third embodiments and the variations thereof, a plurality of rectangular substrates may be placed on the substrate stage 30.

In addition, the first to third embodiments and the variations thereof can also be applied to formation of wiring patterns that connects chips on the substrate P illustrated in FIG. 3B.

The embodiments described above are examples of preferred embodiments of the present invention. However, the present invention is not limited thereto, and various modifications can be made without departing from the scope of the present invention.

What is claimed is:

1. An exposure apparatus comprising:
a spatial light modulator;
a generation unit configured to acquire a measurement result from a measurement system that measures positions of semiconductor chips included in each of sets of the semiconductor chips arranged on a first substrate, determine a wiring pattern that connects the semiconductor chips included in each of the sets based on the measurement result, generate first control data used for control of the spatial light modulator in generating the determined wiring pattern, and store the first control data in a first storage unit; and
an exposure processing unit configured to control the spatial light modulator using the first control data stored in the first storage unit and expose the wiring pattern that connects the semiconductor chips included in each of the sets,
wherein at least one of measurement of the positions of the semiconductor chips on the first substrate, acquisition of the measurement result, determination of the wiring pattern, generation of the first control data, or storage of the first control data in the first storage unit is executed while the exposure processing unit is performing exposure processing on a second substrate different from the first substrate.

2. The exposure apparatus according to claim 1, wherein the first substrate is arranged in plural on a substrate holder included in the exposure apparatus.

3. The exposure apparatus according to claim 1, further comprising:
a plurality of substrate holders; and
the measurement system,
wherein the first substrate is placed on a first substrate holder among the plurality of substrate holders, and
wherein at least one of measurement of positions of semiconductor chips included in each of sets of the semiconductor chips arranged on another substrate placed on a second substrate holder different from the first substrate holder by the measurement system, acquisition of a measurement result of the positions of the semiconductor chips by the generation unit, determination of another wiring pattern that connects the semiconductor chips included in each set on the another substrate placed on the second substrate holder based on the measurement result, generation of second control data used for control of the spatial light modulator in generating the determined another wiring pattern by the generation unit, or storage of the second control data in a second storage unit different from the first storage unit by the generation unit is performed while the exposure processing unit is performing exposure processing of the wiring pattern on the first substrate.

4. The exposure apparatus according to claim 3, further comprising:
a plurality of exchange units configured to exchange substrates held by the plurality of substrate holders, respectively,
wherein one of the plurality of exchange units exchanges the substrate held by the second substrate holder during exposure processing on the first substrate.

5. The exposure apparatus according to claim 1,
wherein the measurement system includes a plurality of measurement devices, and
wherein the plurality of measurement devices measure positions of different semiconductor chips substantially simultaneously.

6. The exposure apparatus according to claim 1,
wherein the spatial light modulator is provided in plural, and
wherein the spatial light modulators form wiring patterns that connect the semiconductor chips in different sets.

7. The exposure apparatus according to claim 2, wherein measurement of positions of the semiconductor chips on a placed substrate, which has been placed on the substrate holder among the first substrates, is performed while placing of an unplaced substrate, which is not placed on the substrate holder, onto the substrate holder is performed.

8. The exposure apparatus according to claim 7, wherein the generation unit generates the first control data in order from the placed substrate on which the measurement of the positions of the semiconductor chips is completed, and stores the first control data in the first storage unit.

9. A wiring pattern forming method, comprising:
acquiring a measurement result from a measurement system that measures positions of semiconductor chips included in each of sets of the semiconductor chips arranged on a first substrate, determining a wiring pattern that connects the semiconductor chips included in each of the sets based on the measurement result, generating first control data used for control of a spatial light modulator in generating the determined wiring pattern, and storing the first control data in a first storage unit; and
controlling the spatial light modulator using the first control data stored in the first storage unit to expose the wiring pattern that connects the semiconductor chips included in each of the sets,
wherein at least one of measuring of the positions of the semiconductor chips on the first substrate, acquiring of the measurement result, determining of the wiring pattern, generating of the first control data, or storing of the first control data in the first storage unit is performed while exposure processing on a second substrate different from the first substrate is performed.

10. The wiring pattern forming method according to claim 9, comprising:
measuring respective positions of a first chip and a second chip included in a first chip set arranged on the first substrate and respective positions of a third chip and a fourth chip included in a second chip set arranged on the first substrate; and
generating pattern data of a first wiring line connecting the first chip and the second chip based on the position of the first chip and the position of the second chip, and pattern data of a second wiring line connecting the third chip and the fourth chip based on the position of the third chip and the position of the fourth chip,
wherein the generating is started during a period in which the measuring is performed.

11. The wiring pattern forming method according to claim 10, comprising:
transferring the pattern data of the first wiring line and the pattern data of the second wiring line to an exposure apparatus including a spatial light modulator,
wherein the transferring is started during a period in which the generating is performed.

12. The wiring pattern forming method according to claim 11, comprising:
performing exposure processing on the second substrate by the exposure apparatus,
wherein the measuring, the generating, and the transferring are started during a period in which the exposure processing is performed.

13. The wiring pattern forming method according to claim 10,
wherein the position of the first chip is a position of a pad of the first chip,
wherein the position of the second chip is a position of a pad of the second chip,
wherein the position of the third chip is a position of a pad of the third chip, and
wherein the position of the fourth chip is a position of a pad of the fourth chip.

14. The wiring pattern forming method according to claim 10, wherein the substrate is a wafer substrate.

15. The wiring pattern forming method according to claim 9, comprising:
performing position measurement in which a position of each of a plurality of chips included in the first substrate arranged on a first tray and a position of each of a plurality of chips included in the second substrate arranged on the first tray are measured; and
performing data generation in which first pattern data, which is pattern data of a wiring line connecting the plurality of chips included in the first substrate based on the position of each of the plurality of chips included in the first substrate, and second pattern data, which is pattern data of a wiring line connecting the plurality of chips included in the second substrate based on the position of each of the plurality of chips included in the second substrate, are generated,
wherein the data generation is started during a period in which the position measurement is performed.

16. The wiring pattern forming method according to claim 15, comprising:
performing data transfer in which the first pattern data and the second pattern data are transferred to an exposure apparatus including a spatial light modulator,
wherein the data transfer is started during a period in which the data generation is performed.

17. The wiring pattern forming method according to claim 16, comprising:
performing substrate exposure in which a plurality of substrates arranged on a second tray are exposed by the exposure apparatus,
wherein the position measurement, the data generation, and the data transfer are started during a period in which the substrate exposure is performed.

18. The wiring pattern forming method according to claim 15, wherein the substrate is a wafer substrate.
